(19) United States
(12) Patent Application Publication
(10) Pub. No.: US 2025/0349690 A1
(43) Pub. Date: Nov. 13, 2025

(54) METAL EDGE FEATURES ON DOUBLE-SIDED PACKAGES

(71) Applicant: Qorvo US, Inc., Greensboro, NC (US)

(72) Inventors: Miles Larkin, Dallas, TX (US); Thomas Scott Morris, Lewisville, NC (US); Charles E. Carpenter, Orlando, FL (US)

(21) Appl. No.: 19/055,876

(22) Filed: Feb. 18, 2025

Related U.S. Application Data
(60) Provisional application No. 63/643,727, filed on May 7, 2024.

(51) Int. Cl. H01L 23/498; H01L 21/48; H01L 23/31; H01L 23/552

(52) U.S. Cl. CPC H01L 23/49827; H01L 21/4839; H01L 21/4842; H01L 23/552; H01L 23/3107

(57) ABSTRACT

Metal edge features on double-sided packages are disclosed. In one aspect, metal such as copper posts may be positioned in a double-sided laminate extending between packages during formation and prior to singulation. Then, during singulation, the post is sawn through. The posts may be used to provide wettable flanks on the side of the package to allow for an inspectable solder fillet. Alternatively, the posts may be used for greater structural integrity. By providing these edge-accessible metal features, designers are able to use double-sided packages with correspondingly small footprints in more environments, allowing for more flexibility in product design.

### PRIORITY APPLICATION

The present application claims priority to U.S. Provisional Patent Application Ser. No. 63/643,727, filed on May 7, 2024, and entitled “METAL EDGE FEATURES ON DOUBLE-SIDED PACKAGES,” the contents of which are incorporated herein by reference in its entirety.

### BACKGROUND

### I. Field of the Disclosure

The technology of the disclosure relates generally to double-sided packages and, more particularly, to double-sided packages with metal edge features.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to squeeze more processing power into increasingly small areas. This pressure has, at least in part, increased the use of double-sided packages where components are positioned on both sides of a substrate. However, the use of such double-sided packages in some environments has not been feasible because of interior electrical connection requirements. Accordingly, improving options for double-sided packages provides room for innovation.

### SUMMARY

Aspects disclosed in the detailed description include metal edge features on double-sided packages. In particular, metal such as copper posts may be positioned in a double-sided laminate extending between packages during formation and prior to singulation. Then, during singulation, the post is sawn through. The posts may be used to provide wettable flanks on the side of the package to allow for an inspectable solder fillet. Alternatively, the posts may be used for greater structural integrity. By providing these edge-accessible metal features, designers are able to use double-sided packages with correspondingly small footprints in more environments, allowing for more flexibility in product design.

In this regard, in one aspect, a double-sided package is disclosed. The double-sided package includes a metallization layer with internal metal layers and vias electrically coupling a first side surface contact on a first side to a second side surface contact on a second opposite side and a component or die positioned on the first side of the metallization layer, the component or die electrically coupled to the first side surface contact. The double-sided package also includes a metal edge feature element mounted on the first side of the metallization layer such that at least a portion of the metal edge feature element is exposed at a circumferential edge of the double-sided package, the metal edge feature element electrically coupled to the internal metal layers of the metallization layer.

In another aspect, a double-sided package is disclosed. The double-sided package includes a metallization layer with internal metal layers and vias electrically coupling a first side surface contact on a first side to a second side surface contact on a second opposite side and a component or die positioned on the first side of the metallization layer, the component or die electrically coupled to the first side surface contact. The double-sided package also includes a metal edge feature element mounted on the first side of the metallization layer such that at least a portion of the metal edge feature element is exposed at a circumferential edge of the double-sided package, the metal edge feature element comprising a post configured to provide structural support for the double-sided package.

In another aspect, a method of forming a double-sided package is disclosed. The method includes forming a metallization layer strip with internal interconnects and vias, the metallization layer strip comprising a first surface contact on a first side and a second surface contact on a second side opposite the first side, and forming a metal edge feature elements on the first side of the metallization layer strip such that they extend across a saw cut zone. The method also includes singulating the metallization layer strip by cutting through the metal edge feature elements.

### BRIEF DESCRIPTION OF THE DRAWINGS

FIG. 1 is a plan view of a first side of a laminate strip during package formation;

FIG. 2 is a plan view of the laminate strip of FIG. 1 with a die or component positioned thereon;

FIG. 3 is a plan view of a single package singulated from the laminate strip of FIG. 2 with metal edge features according to an exemplary aspect of the present disclosure;

FIG. 4 is a plan view of a first side of a laminate strip during package formation;

FIG. 5 is a plan view of the laminate strip of FIG. 4 with a die or component positioned thereon;

FIG. 6 is a plan view of a single package singulated from the laminate strip of FIG. 5 with metal edge posts according to an exemplary aspect of the present disclosure;

FIG. 7 is a flowchart illustrating an exemplary process for forming a double-sided package with metal edge features according to aspects of the present disclosure;

FIGS. 8A-8H illustrate side cross-sectional views of intermediate products formed by the process of FIG. 7 that results in the package of FIG. 3;

FIG. 8I illustrates a finished product having wettable flanks from the process of FIG. 7;

FIG. 9 is a flowchart illustrating an exemplary process for forming the double-sided package of FIG. 6 according to aspects of the present disclosure;

FIGS. 10A-10E illustrate side cross-sectional views of intermediate products formed by the process of FIG. 9 that results in the package of FIG. 6; and

FIG. 11 is a block diagram of a computing device with a wireless transceiver, which may include the double-sided package with metal edge features made according to the process of FIG. 7 or 9 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include metal edge features on double-sided packages. In particular, metal such as copper posts may be positioned in a double-sided laminate extending between packages during formation and prior to singulation. Then, during singulation, the post is sawn through. The posts may be used to provide wettable flanks on the side of the package to allow for an inspectable solder fillet. Alternatively, the posts may be used for greater structural integrity. By providing these edge-accessible metal features, designers are able to use double-sided packages with correspondingly small footprints in more environments, allowing for more flexibility in product design.

More specifically, a laminate strip capable of having a plurality of packages formed therefrom is formed with internal metallization layers, including metal features that extend across a saw cut. The sides of the laminate strip are populated with components and/or dies, covered by a mold material, and then singulated. During singulation, the saw cuts through the metal features such that the metal features are exposed at the sides of the final package. Additional package formation may be formed, including, for example, shielding formation or the like.

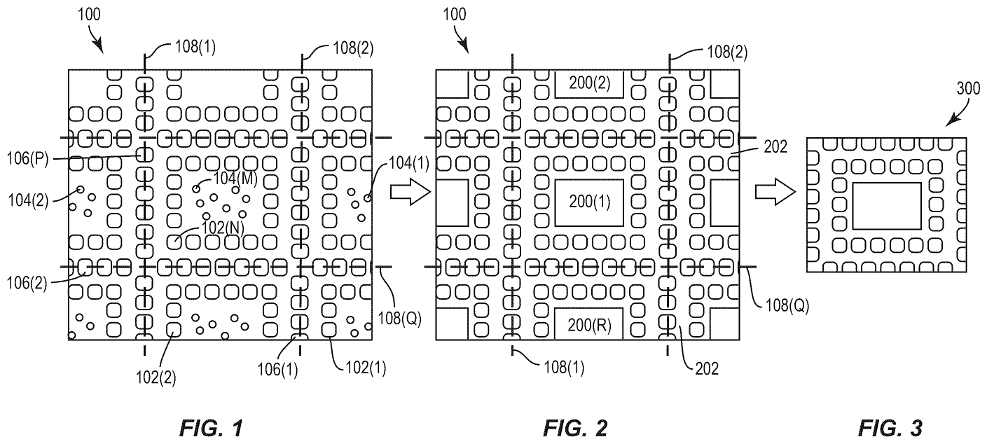

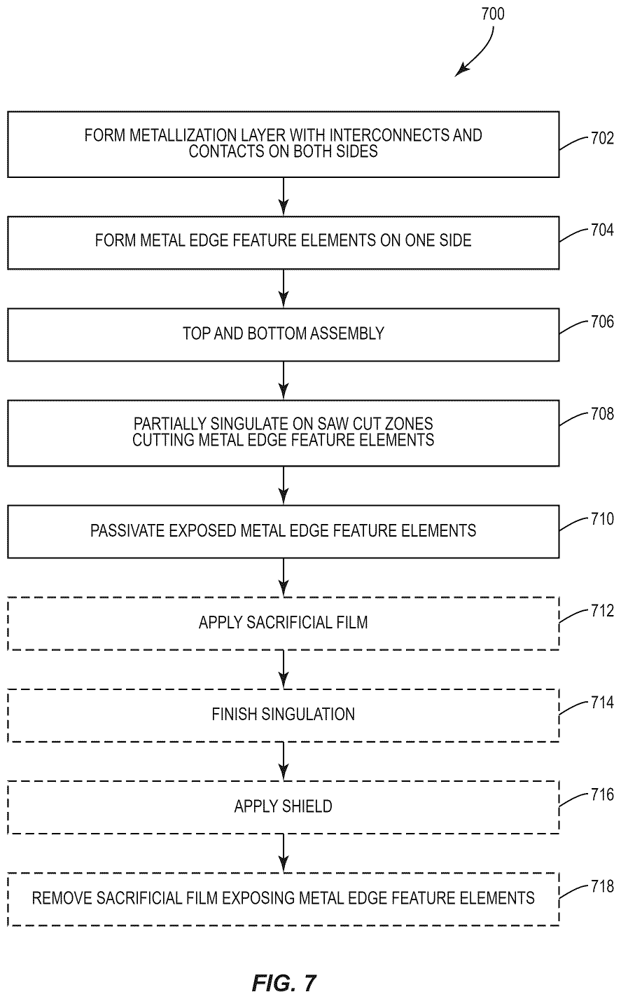

In this regard, FIG. 1 is a plan view of a first side of a laminate strip 100. The laminate strip 100 may include internal metallization layers (not shown) coupled to surface contacts 102(1)-102(N) configured to be used for wire bond contacts as well as surface contacts 104(1)-104(M) that are configured to couple directly to die bumps or the like. Note that the surface contacts 102(1)-102(N) may alternatively be designed to provide an external contact for that side of the laminate strip 100. Still, further metal edge feature elements 106(1)-106(P) are formed in rows and columns that correspond to saw cut zones 108(1)-108(Q). That is, the metal edge feature elements 106(1)-106(P) are large enough to fall on both sides of the saw cut zones 108(1)-108(Q) such that when the cut is made, portions of the metal edge feature elements 106(1)-106(P) will be exposed on a lateral edge of the laminate as better seen in FIG. 3, discussed below. In an exemplary aspect, the metal edge feature elements 106(1)-106(P) are formed from a conductive material such as copper (Cu), which exhibits moderate structural strength. Alternatively, other conductors such as silver (Ag), gold (Au), aluminum (Al), or the like may be used. In an exemplary aspect, the metal edge feature element 106(1)-106(P) may be between 60-150 micrometers in thickness.

While not shown in FIG. 1, it should be appreciated that the opposite side of the laminate strip 100 may also have contacts suitable for electrical connection to components. Also, while, as shown, the surface contacts 102(1)-102(N) and 104(1)-104(M) are both present on the laminate strip 100, there may be instances where only surface contacts 102(1)-102(N) or surface contacts 104(1)-104(M) are present. For example, many automotive applications will not include surface contacts 102(1)-102(N).

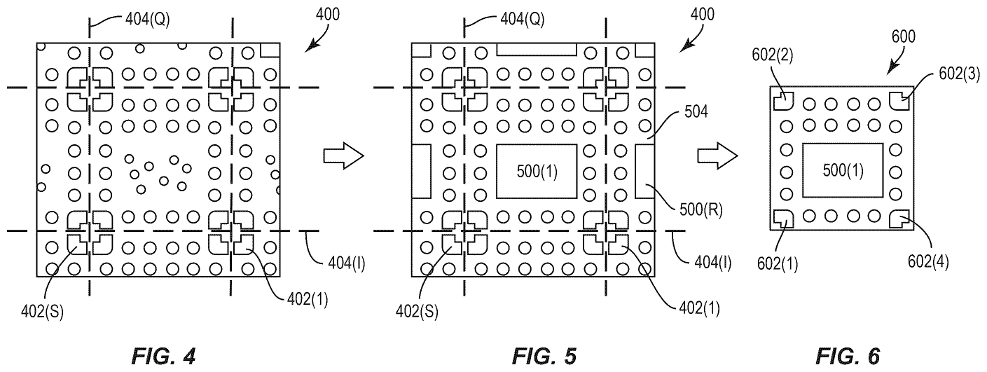

FIG. 2 illustrates the laminate strip 100 after components or dies 200(1)-200(R) have been directly coupled to the surface contacts 104(1)-104(M). Additional wire bond connections may be made between the dies 200(1)-200(R) and the surface contacts 102(1)-102(N). Still further, mold material 202 may be placed over and around the dies 200(1)-200(R).

Again, while not shown in FIG. 2, the opposite side of the laminate strip 100 may also have dies or components attached thereto with mold and other processing steps performed.

The laminate strip 100 is then singulated by cutting along the saw cut zones 108(1)-108(Q) to form a singulated double-sided package 300, illustrated in FIG. 3. The metal edge feature elements 106(1)-106(P) now have an exposed surface on a lateral edge of the singulated double-sided package 300. This exposed surface may be considered a wettable flank, and a side view is also seen in FIG. 81. The presence of the wettable flank in this fashion provides inspectable solder fillets on the singulated double-sided package 300.

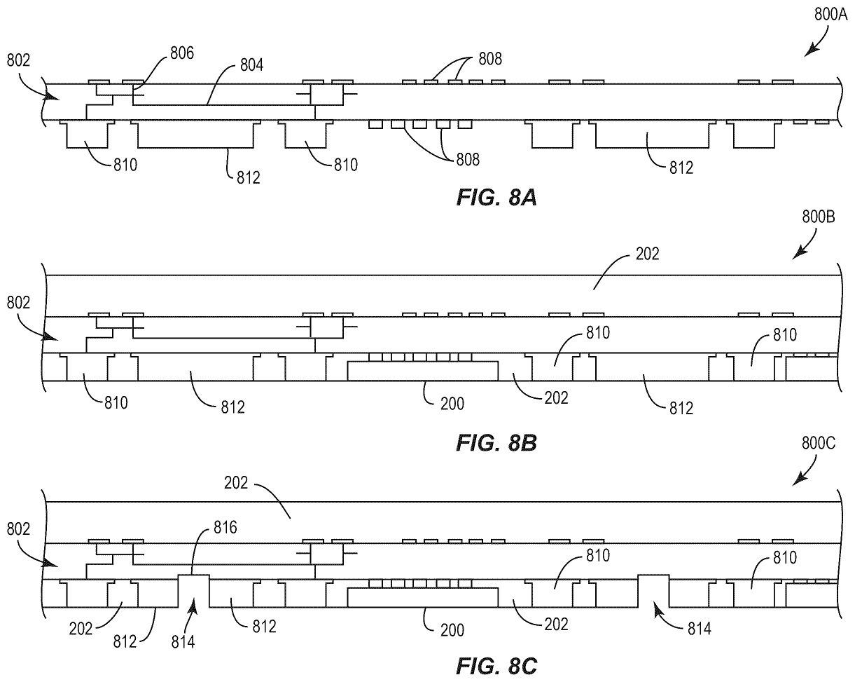

In an alternate aspect, wettable flanks may not be needed, but greater structural integrity may be desired so as to survive, for example, drop shock. FIGS. 4-6 illustrate another exemplary aspect where the metal edge feature elements provide posts that add structural integrity.

In this regard, FIG. 4 illustrates a double-sided laminate strip 400 that is similar in many ways to the laminate strip 100, but instead of metal edge feature elements 106(1)-106(P) that are arranged in rows and columns corresponding to saw cut zones 108(1)-108(Q), the laminate strip 400 includes metal edge feature elements 402(1)-402(S), which are loops, possibly segmented or having gaps, centered on the intersections of saw cut zones 404(1)-404(Q). As illustrated, the loops are generally rectilinear or square, but an annulus shape could also be used. The loops could be segmented which would allow mold compound to flow into the interior portion of the loops. Other structures that allow the mold to flow into the interior portion may also be used (e.g., windowed or perforated walls, partial walls along a portion that create a place for mold to flow thereover (or thereunder)). The tradeoff between mold flow and structural integrity of the posts may vary depending on design criteria (e.g., a design that requires less structural support may have more apertures for mold flow and vice versa). Again, the metal edge feature elements 402(1)-402(S) may be made from copper or other rigid metal. For this purpose, softer metals like gold are less appropriate.

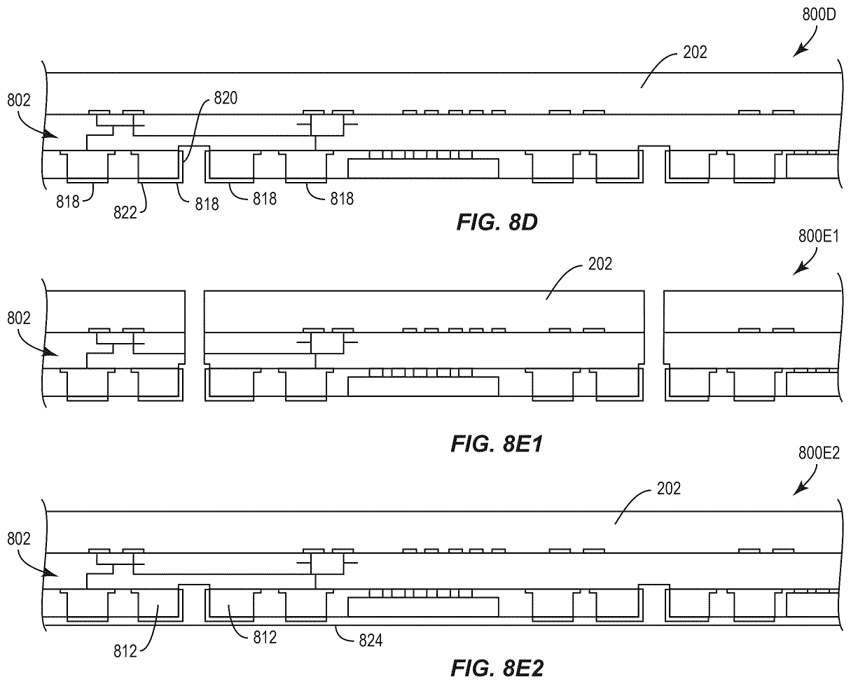

FIG. 5 illustrates the double-sided laminate strip 400 after attaching dies 500(1)-500(R), application of mold compound 504, and the like.

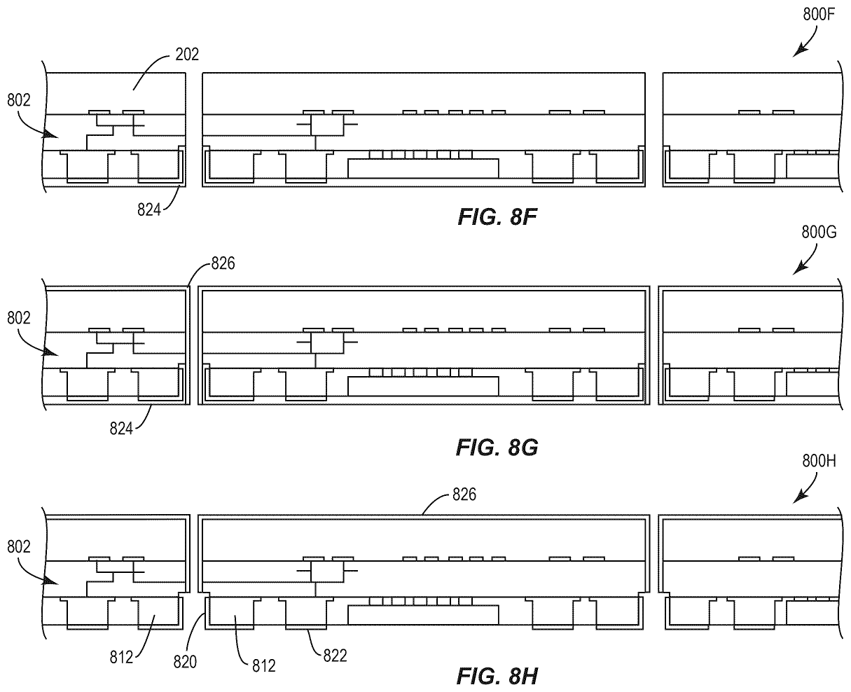

FIG. 6 illustrates a singulated double-sided package 600 where the metal edge feature elements 402(1)-402(S) have been cut through such that a generally L-shaped post 602(1)-602(4) is present at corners of the singulated double-sided package 600. Note that if the metal edge feature elements 402(1)-402(S) are annular, the posts 602(1)-602(4) will be more C-shaped or arcuate than L-shaped.

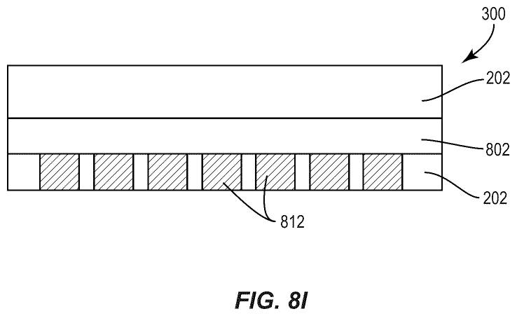

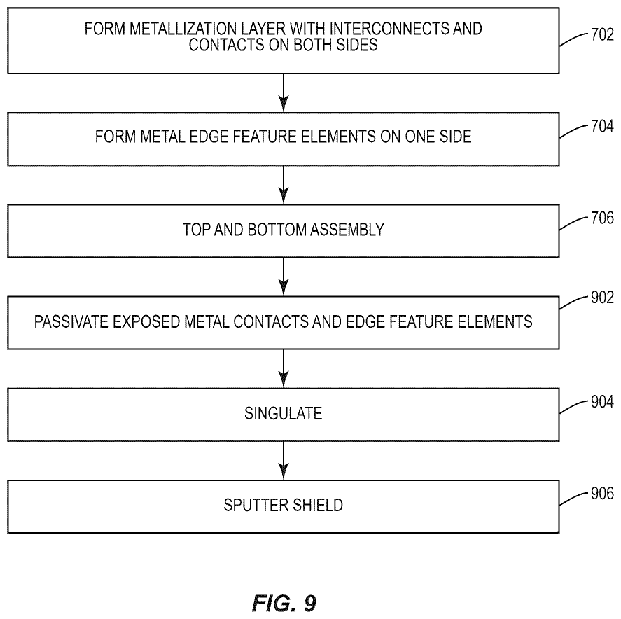

FIG. 7 provides a process 700 for making a singulated double-sided package 300 with an optional shield. FIGS. 8A-8H are used to show the intermediate products 800A-800H of the process 700. In particular, the process 700 begins by forming a metallization layer 802 (which may equivalently be referred to as a laminate structure) with internal conductive interconnects 804 and vias 806 sandwiched between dielectric layers (not labeled) and external contacts 808, 810 on both sides (block 702, FIG. 8A). External contacts 808 may be configured to couple to a die 200, as better shown in FIG. 8B, and external contacts 810 may be configured to provide electrical contact to another laminate (e.g., a motherboard or the like).

The process 700 continues by forming metal edge feature elements 812 on one side of the metallization layer 802 (block 704, FIG. 8A). Note that the metal edge feature elements 812 may be formed concurrently with the formation of external contacts 810. Relevantly, and as discussed above, the metal edge feature elements 812 cross the saw-cut zones between different packages being formed on the metallization layer 802.

Top and bottom assembly is then performed (block 706, FIG. 8B). This assembly may include die attaching of die 200 of a first side of the metallization layer 802, surface mounting, wire bonding, molding with mold material 202, topside grinding and bottom-side grinding to expose electrical contacts, and the like. Other components, dies, circuits, or the like may be formed on the second or opposite side of the metallization layer 802.

The metallization layer 802 is then positioned with the side having the metal edge feature elements 812 “up,” and the metallization layer 802 is partially singulated on the saw-cut zones thereby cutting the metal edge feature elements 812 (block 708, FIG. 8C) to form trenches 814 at least down to a top dielectric layer 816 (and potentially deeper, although not all the way through) of the metallization layer 802. This partial singulation is sometimes referred to as sub-dicing.

The exposed surface of the metal edge feature elements 812 is passivated (block 710, FIG. 8D) with a layer 818 on both of the lateral side surface 820 as well as the top surface 822. The passivation may be done with organic solderability preservative (OSP), electroless nickel immersion gold (ENIG) plating, electroless nickel electroless palladium immersion gold (ENEPIG) plating, or the like. If a shield is to be applied, a sacrificial film 824 is applied (block 712, FIG. 8E2), and then singulation is finished (block 714, FIG. 8E1 or FIG. 8F) using a blade thinner than the blade used to make the partial singulation cut of block 708. If no shield is to be applied, then block 712 may be skipped, and the process ends after block 714.

If a shield is to be applied, after singulation, the shield 826 is applied (block 716, FIG. 8G). The shield may be applied using sputter shielding or the like and is applied to the side of the singulated double-sided package 300 that does not include the metal edge feature elements 812, although the sputtering may extend to cover portions of the sacrificial film 824. The sacrificial film 824 is then removed, thereby exposing the metal edge feature elements 812 (block 718, FIG. 8H) on the lateral sides of the singulated double-sided package 300.

The end result of this process 700 is the singulated double-sided package 300, illustrated in FIGS. 3 and 81, where the metal edge feature elements 812 form a wettable flank amenable to inspectable soldering. That is, the metal edge feature elements 812 are effectively positioned at a circumferential edge of the double-sided package such that they are exposed laterally (as opposed to a top-bottom exposure like external contacts 810).

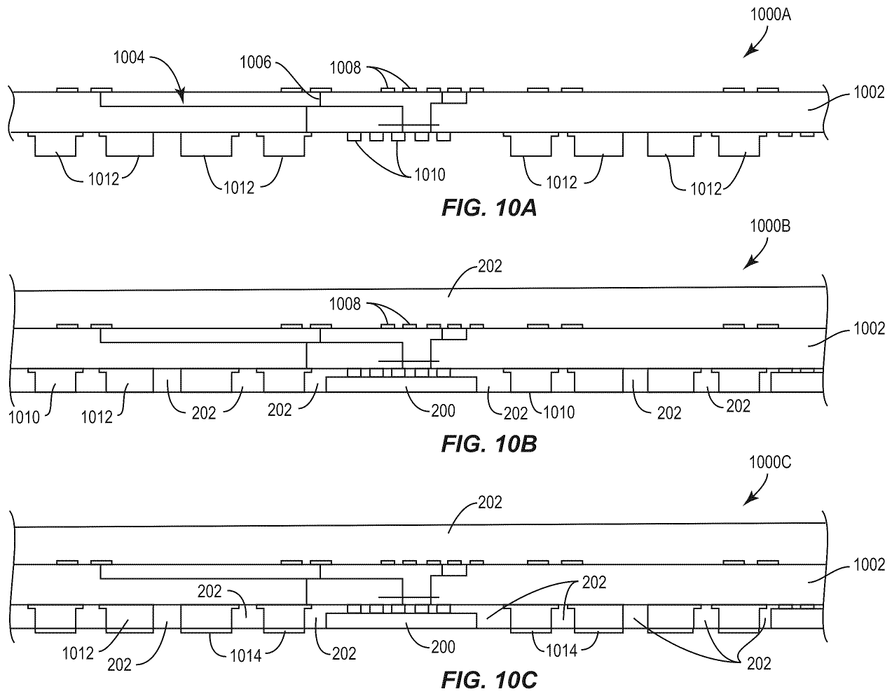

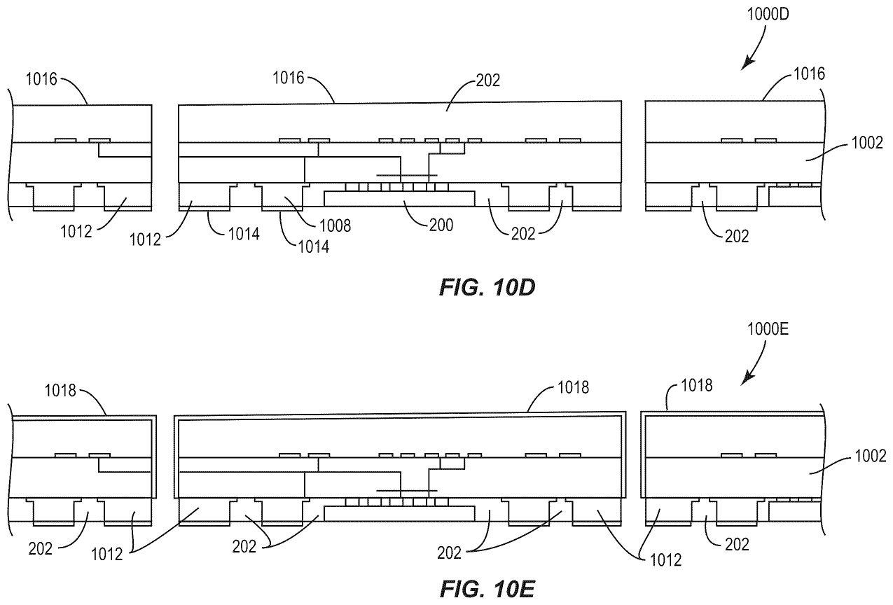

A process 900 for making the singulated double-sided package 600 of FIG. 6 is similar and set forth in FIG. 9 with additional reference to FIGS. 10A-10E for views of the intermediate products. The process 900 begins with essentially the same steps as process 700 but with reference to intermediate products 1000A-1000E of FIGS. 10A-10E. That is, begins by forming a metallization layer 1002 with internal conductive interconnects 1004 and vias 1006 sandwiched between dielectric layers (not labeled) and external contacts 1008, 1010 on both sides (block 702, FIG. 10A). External contacts 1008 may be configured to couple to a die 200, as better shown in FIG. 10B and external contacts 1010 may be configured to provide electrical contact to another laminate (e.g., a motherboard or the like).

The process 900 continues by forming metal edge feature elements 1012 on one side of the metallization layer 1002 (block 704, FIG. 10A). In this case, the loops of the metal edge feature elements may be, as noted above, segmented or include some aperture to allow mold flow therethrough. Note that the metal edge feature elements 1012 may be formed concurrently with the formation of external contacts 1010. Relevantly, and as discussed above, the metal edge feature elements 1012 cross the saw-cut zones between different packages being formed on the metallization layer 1002.

Top and bottom assembly is then performed (block 706, FIG. 10B). This assembly may include die attaching of die 200, surface mounting, wire bonding, molding with mold material 202, topside grinding and bottom-side grinding to expose electrical contacts, and the like. The mold will flow through gaps between the segments of the loops of the metal edge feature elements 1012.

The process 900 then continues by passivating exposed metal contacts 1010 and edge feature elements 1012 (block 902, FIG. 10C) as shown by layers 1014. The packages are then singulated (block 904, FIG. 10D) to create separate packages 1016. A shield 1018 is then sputtered on the packages 1016 (block 906, FIG. 10E. This shield 1018 may be coupled to ground.

The metal edge features on double-sided packages, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter. Note further that these packages are also well-suited for use in automobiles which may have an explicit requirement for inspectable solder fillets.

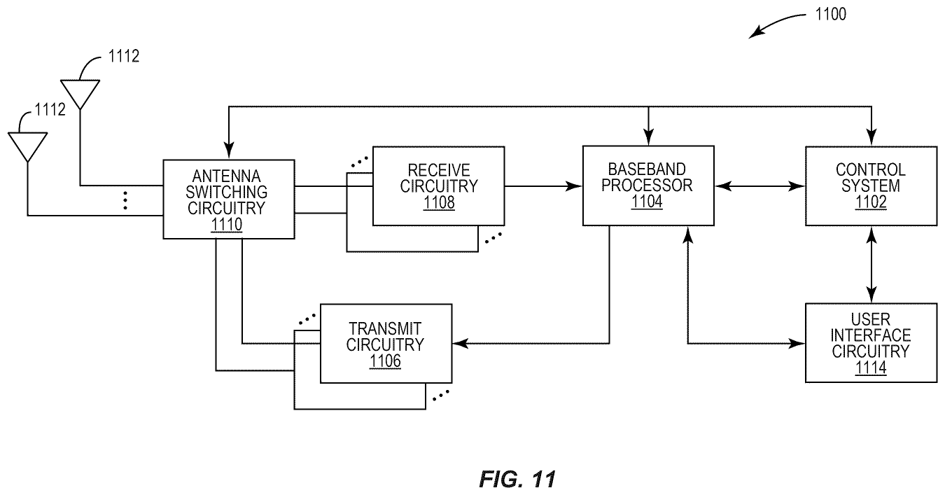

FIG. 11 is a schematic diagram of an exemplary communication device 1100 wherein the double-sided packages of the present disclosure can be provided. Herein, the communication device 1100 can be any type of communication devices, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 1100 will generally include a control system 1102, a baseband processor 1104, transmit circuitry 1106, receive circuitry 1108, antenna switching circuitry 1110, multiple antennas 1112, and user interface circuitry 1114. In a non-limiting example, the control system 1102 can be a field-programmable gate array (FPGA) or an application-specific integrated circuit (ASIC), as an example. In this regard, the control system 1102 can include at least a microprocessor(s), an embedded memory circuit(s), and a communication bus interface(s). It is possible that the control system 1102 could be provided in a double-sided package of the present disclosure. The receive circuitry 1108 receives radio frequency signals via the antennas 1112 and through the antenna switching circuitry 1110 from one or more base stations. A low noise amplifier and a filter of the receive circuitry 1108 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 1104 processes the digitized received signal to extract the information or data bits conveyed in the received signal. This processing typically comprises demodulation, decoding, and error correction operations. The baseband processor 1104 is generally implemented in one or more digital signal processors (DSPs) and ASICs. The baseband processor 1104 may also be instantiated in a double-sided package of the present disclosure.

For transmission, the baseband processor 1104 receives digitized data, which may represent voice, data, or control information, from the control system 1102, which it encodes for transmission. The encoded data is output to the transmit circuitry 1106, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 1112 through the antenna switching circuitry 1110 to the antennas 1112. The multiple antennas 1112 and the replicated transmit and receive circuitries 1106, 1108 may provide spatial diversity. Modulation and processing details will be understood by those skilled in the art. Note also that the receive circuits 1106 or the transmit circuits 1108 may also be instantiated in the double-sided packages of the present disclosure.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A double-sided package, comprising:
a metallization layer with internal metal layers and vias electrically coupling a first side surface contact on a first side to a second side surface contact on a second opposite side;
a component or die positioned on the first side of the metallization layer, the component or die electrically coupled to the first side surface contact; and
a metal edge feature element mounted on the first side of the metallization layer such that at least a portion of the metal edge feature element is exposed at a circumferential edge of the double-sided package, the metal edge feature element electrically coupled to the internal metal layers of the metallization layer.

2. The double-sided package of claim 1, further comprising an external contact positioned on the first side of the metallization layer, the external contact electrically coupled to at least one internal metal layer.

3. The double-sided package of claim 1 integrated into an automobile.

4. The double-sided package of claim 1, further comprising a second component or die positioned on the second side of the metallization layer and electrically coupled to a second second side surface contact.

5. The double-sided package of claim 4, further comprising a mold material positioned around and over the second component or die.

6. The double-sided package of claim 5, further comprising a shield positioned over and around at least a portion of the mold material.

7. A double-sided package, comprising:
a metallization layer with internal metal layers and vias electrically coupling a first side surface contact on a first side to a second side surface contact on a second opposite side;
a component or die positioned on the first side of the metallization layer, the component or die electrically coupled to the first side surface contact; and
a metal edge feature element mounted on the first side of the metallization layer such that at least a portion of the metal edge feature element is exposed at a circumferential edge of the double-sided package, the metal edge feature element comprising a post configured to provide structural support for the double-sided package.

8. The double-sided package of claim 7, further comprising an external contact on the first side of the metallization layer, the external contact having a height equal to a height of the metal edge feature element, the external contact electrically coupled to the internal metal layers of the metallization layer.

9. The double-sided package of claim 8, further comprising mold material positioned over and around the die or component and around at least a portion of the external contact.

10. The double-sided package of claim 8, further comprising a passivation layer on the external contact.

11. The double-sided package of claim 7, further comprising a shield positioned over the second side of the metallization layer.

12. The double-sided package of claim 7 integrated into a communication device.

13. A method of forming a double-sided package, comprising:
forming a metallization layer strip with internal interconnects and vias, the metallization layer strip comprising a first surface contact on a first side and a second surface contact on a second side opposite the first side;
forming a metal edge feature elements on the first side of the metallization layer strip such that they extend across a saw cut zone; and
singulating the metallization layer strip by cutting through the metal edge feature elements.

14. The method of claim 13, wherein forming the metal edge feature elements comprises forming a metal post.

15. The method of claim 13, further comprising attaching a die or component to the first surface contact.

16. The method of claim 15, further comprising adding an external contact to the first side.

17. The method of claim 16, further comprising adding a mold around and over the die or component.

18. The method of claim 17, further comprising grinding the mold to expose the external contact.

19. The method of claim 13, wherein singulating comprises:
partially singulating;
applying a passivation layer on portion of a metal edge feature element exposed by the partial singulating; and
applying a sacrificial film over exposed portions of the metal edge feature elements.

20. The method of claim 19, further comprising applying a shield to the second side of the metallization layer strip.
